(19) United States
(12) Patent Application Publication
(10) Pub. No.: US 2026/0047469 A1
(43) Pub. Date: Feb. 12, 2026

(54) ELECTRONIC MODULE

(71) Applicant: SHINDENGEN ELECTRIC MANUFACTURING CO., LTD., Tokyo (JP)

(72) Inventors: Soichiro UMEDA, Asaka City (JP); Atsushi KYUTOKU, Asaka City (JP)

(21) Appl. No.: 19/361,764

(22) Filed: Oct. 17, 2025

Related U.S. Application Data
(63) Continuation of application No. PCT/JP2024/027747, filed on Aug. 2, 2024.

(30) Foreign Application Priority Data
Sep. 28, 2023 (JP) 2023-168489

(51) Int. Cl. H01L 23/00; H01L 23/49

(52) U.S. Cl. CPC H01L 24/32; H01L 23/49; H01L 2224/32059

(57) ABSTRACT

An electronic module is provided that suppresses mispositioning of an internal connection terminal and a chip spacer, suppresses rotation of the chip spacer when solder is melted, and improves desired self-alignment effects. The electronic module includes an electronic element, at least one conductive internal connection terminal that is electrically connected to the electronic element, and a chip spacer that is formed between the electronic element and a lower end surface of the internal connection terminal. The chip spacer is bonded to the electronic element via a conductive bonding material, and at least one recess that has a larger diameter than the internal connection terminal is formed in an upper surface of the chip spacer.

### CROSS-REFERENCE TO RELATED APPLICATION

This application is a continuation of International Application No. PCT/JP2024/027747, filed on Aug. 2, 2024, which claims all the benefits of Japanese Patent Application No. 2023-168489 filed on Sep. 28, 2023.

### TECHNICAL FIELD

The present invention relates to an electronic module.

### BACKGROUND

In the related art, an electronic module including a semiconductor element and an internal connecting terminal that connects electrodes of the semiconductor element and a wiring pattern formed on a substrate has been known. Meanwhile, an electronic module including a semiconductor element, a substrate on which the semiconductor element is mounted, a pin terminal serving as an internal connecting terminal connected to a wiring pattern formed on the substrate, and a lead frame that supports the pin terminal and that electrically connects electrodes of the semiconductor element and the pin terminal has been known (refer to Patent Document 1 below). Furthermore, in some electronic modules of this type, the internal connecting terminal is connected to the electrodes of the semiconductor element instead of being connected to the wiring pattern. In such an electronic module, a configuration in which stress is reduced by connecting the semiconductor element to the internal connecting terminal via the chip spacer can be considered.

Meanwhile, as shown in FIG. 5, an electronic module in which a semiconductor element 320 is bonded onto an insulating substrate 312 via a solder BM 30 and a chip spacer 318 is bonded, via a solder BM 20, to a lower end side of an internal connecting terminal 334 inserted into a through-hole (not shown) formed in a lead frame (not shown) has also been known.

### CITATION LIST

### Patent Document

Patent Document 1: JP 6850938 B2

### SUMMARY

### Problem to be Solved by the Invention

However, in the process of bonding the internal connecting terminal 334 and the chip spacer 318, the solder BM 20 between the internal connecting terminal 334 and the chip spacer 318 flows out, so that misalignment between the internal connecting terminal 334 and the chip spacer 318 occurs when the solder melts, and it is difficult to achieve a desired self-alignment effect, which is a problem.

In addition, when the chip spacer 318 is used as a buffer material, in the case of a chip including electrodes on a front surface thereof, in order to reduce a resistance component, it is necessary to increase the shape of the chip spacer 318 according to the number of chip electrodes.

In this case, the problem is to realize a structure in which misalignment between the internal connecting terminal 334 and the chip spacer 318 and the rotation of the chip spacer 318 when the solder melts are suppressed.

Therefore, the invention has been made in view of the above-described problems, and an object of the invention is to provide an electronic module that suppresses misalignment between an internal connecting terminal and a chip spacer, and that improves a desired self-alignment effect.

In addition, an object of the invention is to provide an electronic module that suppresses misalignment between an internal connecting terminal and a chip spacer and the rotation of the chip spacer when a solder melts, and that improves a desired self-alignment effect, when the shape of the chip spacer is increased according to the number of chip electrodes.

### Means for Solving Problem

An electronic module of the invention includes an electronic element; at least one internal connecting terminal electrically connected to the electronic element, and having conductivity; and a chip spacer formed between a lower end surface of the internal connecting terminal and the electronic element. The chip spacer is bonded to the electronic element via a conductive bonding material, and at least one depression having a larger diameter than the internal connecting terminal is formed on an upper surface of the chip spacer.

### Effect of the Invention

According to the electronic module of the invention, since at least one depression having a larger diameter than the internal connecting terminal is formed on the upper surface of the chip spacer, it is possible to provide the electronic module that suppresses misalignment between the internal connecting terminal and the chip spacer, and that improves a desired self-alignment effect.

In addition, according to the electronic module of the invention, it is possible to provide the electronic module that suppresses misalignment between the internal connecting terminal and the chip spacer and the rotation of the chip spacer when a solder melts, and that improves a desired self-alignment effect, when the shape of the chip spacer is increased according to the number of chip electrodes.

### BRIEF DESCRIPTION OF THE DRAWINGS

FIG. 1 is a perspective view showing an appearance of an electronic module 100 according to a first embodiment;

FIGS. 2A-2C together show views for describing a chip spacer in the first embodiment; in which FIG. 2A is a plan view showing one pin terminal and the chip spacer of the electronic module according to the first embodiment, FIG. 2B is a longitudinal cross-sectional view of FIG. 2A, and FIG. 2C is a perspective view showing an appearance of the chip spacer;

FIG. 3 is a view showing a cross-sectional structure of the electronic module 100 according to the first embodiment;

FIG. 4 is a view for when a plurality of internal connecting terminals that are pin terminals are used;

FIG. 5 is a view showing a cross-sectional structure of the electronic module 100 according to a second embodiment; and

FIG. 6 is a view for describing an electronic module according to the related art.

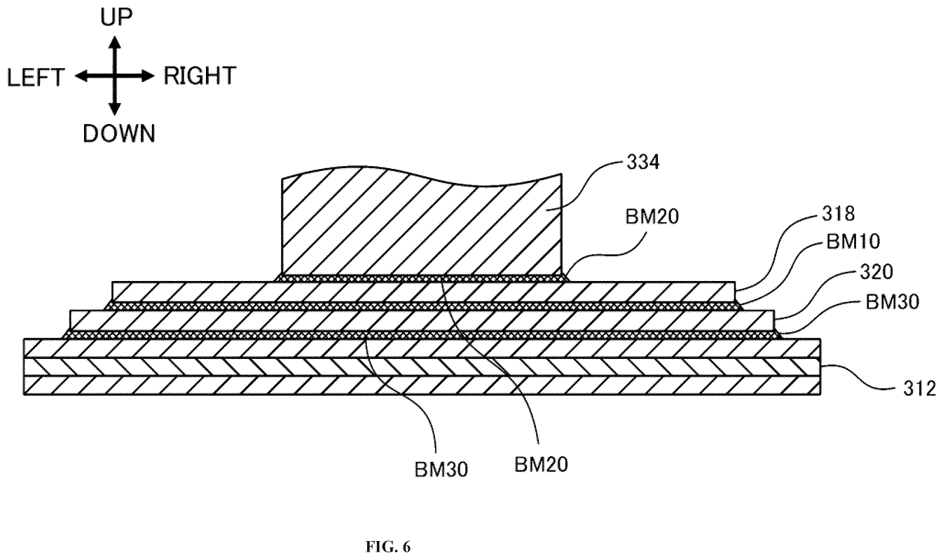

### DETAILED DESCRIPTION OF THE EMBODIMENTS

Hereinafter, an electronic module according to the invention will be described. Embodiments to be described below do not limit the invention according to the claims. In addition, all of elements and combinations thereof described in the embodiments are not necessarily essential to the invention.

### First Embodiment

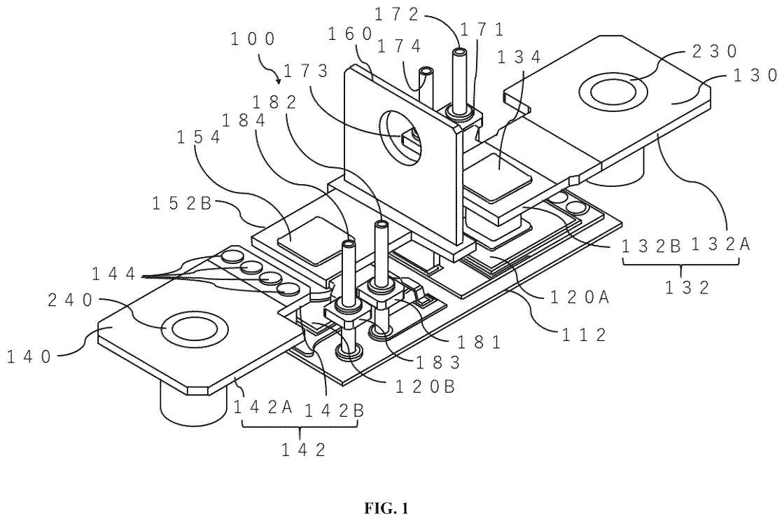

As shown in FIG. 1, an electronic module 100 according to a first embodiment has a substantially rectangular parallelepiped shape that is long in a front-rear direction and that is flat in an up-down direction. The electronic module 100 includes an insulating substrate 112, an electronic element 120, a first terminal 130, a second terminal 140, a third terminal 160, a first connecting frame 132B, a second connecting frame 142B, a third connecting frame 152B, and a sealing resin (not shown).

The insulating substrate 112 is a DCB (direct copper bonding) ceramic substrate, on the upper surface of which a circuit wiring is formed, and on the lower surface (back surface) of which a metal plate for heat dissipation is formed. Two electronic elements 120 are disposed, for example, on the circuit wiring formed on one surface of the insulating substrate 112. Incidentally, the insulating substrate 112 may be a printed circuit board or the like. The insulating substrate 112 is formed in a rectangular flat plate shape, and it is preferable that the insulating substrate 112 is disposed at a central portion in the front-rear direction that is a longitudinal direction of the electronic module 100.

The two electronic elements 120A and 120B are each disposed on the circuit wiring on the one surface of the insulating substrate 112. The electronic elements 120A and 120B are configured as semiconductor elements, and, for example, power metal-oxide-semiconductor field-effect transistors (MOSFETs) can be used, but IGBTs, thyristors, diodes, and other appropriate elements can be used. Each of the electronic elements 120A and 120B includes electrodes (not shown) on both surfaces of a semiconductor substrate, a source electrode and a gate electrode are formed on a front surface of the semiconductor substrate, and a drain electrode (not shown) is formed on a back surface thereof.

In the electronic element 120A, the source electrode is connected to the first terminal 130 via a chip spacer 122, an internal connecting terminal 134, and the first connecting frame 132B. In addition, the source electrode is connected to a pin terminal 172, which serves as a sense terminal, via a wire, a circuit wiring, or the like. The gate electrode is connected to a pin terminal 174 via a circuit wiring. The drain electrode is electrically connected to a circuit wiring formed on a lower surface side of the semiconductor substrate. Incidentally, in an example of FIG. 1, the internal connecting terminal 134 is a pin terminal having a substantially polygonal shape when viewed in the up-down direction, more specifically a substantially quadrilateral shape, and further specifically a substantially quadrilateral shape with arc-shaped corners protruding outward.

In the electronic element 120B, the source electrode is connected to the drain electrode of the electronic element 120A on the front side via a chip spacer (not shown), an internal connecting terminal 154, the third connecting frame 152B, and a circuit wiring, and is connected to the third terminal 160 via the third connecting frame 152B. In addition, the source electrode is connected to the pin terminal 172, which serves as a sense terminal, via a wire, a circuit wiring, or the like. The gate electrode is connected to the pin terminal 174 via a circuit wiring. The drain electrode is electrically connected to the second connecting frame 142B via a circuit wiring formed on a lower surface side of the semiconductor substrate. Incidentally, in the example of FIG. 1, the internal connecting terminal 154 is a pin terminal having a substantially polygonal shape when viewed in the up-down direction, more specifically a substantially quadrilateral shape, and further specifically a substantially quadrilateral shape with arc-shaped corners protruding outward (hereinafter, when the internal connecting terminal 154 is viewed in the up-down direction, a substantially polygonal shape, more specifically a substantially quadrilateral shape, and further specifically a substantially quadrilateral shape with arc-shaped corners protruding outward may be simply referred to as a substantially polygonal shape).

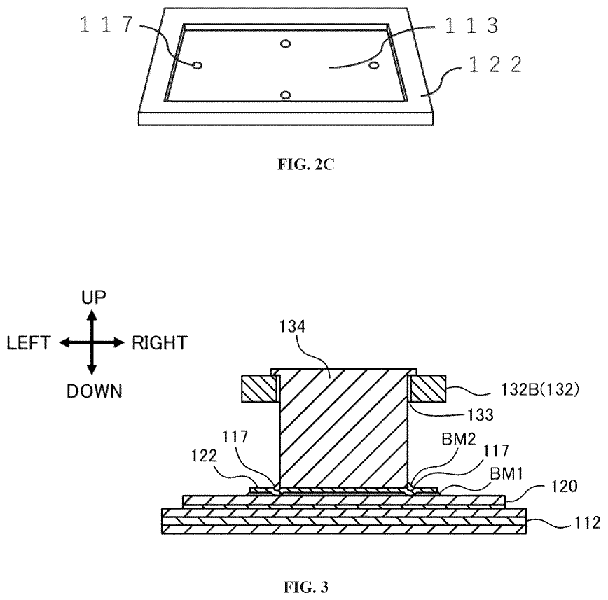

The first connecting frame 132B and the first terminal 130 are integrally formed from the same plate material 132. That is, a portion of the plate material 132, which is embedded in the sealing resin, corresponds to the first connecting frame 132B. The first connecting frame 132B has a through-hole 133 (refer to FIG. 3) penetrating through the first connecting frame 132B in the up-down direction, and is electrically connected to the first terminal 130. The through-hole 133 has a substantially polygonal shape when viewed in the up-down direction, more specifically a substantially quadrilateral shape, and further specifically a substantially quadrilateral shape with arc-shaped corners protruding outward (hereinafter, when the through-hole 133 is viewed in the up-down direction, a substantially polygonal shape, more specifically a substantially quadrilateral shape, and further specifically a substantially quadrilateral shape with arc-shaped corners protruding outward may be simply referred to as a substantially polygonal shape). An upper end portion of the internal connecting terminal 134 is fitted into the through-hole 133, and the first connecting frame 132B and the electrodes of the electronic element 120 are connected by the internal connecting terminal 134. Incidentally, the shape of the through-hole is not limited to a substantially polygonal shape, and may be a columnar shape or the like.

The internal connecting terminal 134 is made of metal having a substantially polygonal shape, and electrically connects the electrodes of the electronic element 120 and the first connecting frame 132B. The internal connecting terminal 134 is fixed to and also electrically connected to the first connecting frame 132B, for example, by press-fitting. Incidentally, the shape of the internal connecting terminal is not limited to a substantially polygonal shape, and may be a columnar shape or the like.

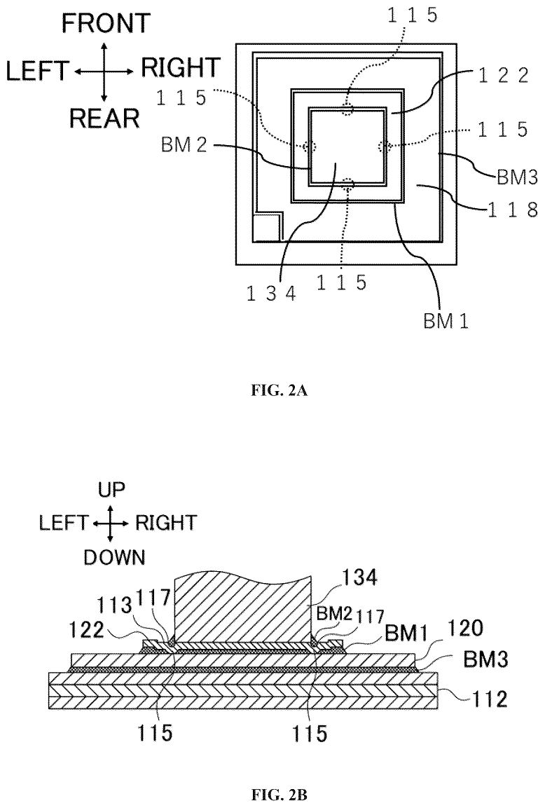

As shown in FIGS. 2A and 2C, the chip spacer 122 is formed in a substantially polygonal shape when viewed in the up-down direction, more specifically a substantially quadrilateral shape, and further specifically a substantially quadrilateral shape with arc-shaped corners protruding outward (hereinafter, when the internal connecting terminal 154 is viewed in the up-down direction, a substantially polygonal shape, more specifically a substantially quadrilateral shape, and further specifically a substantially quadrilateral shape with arc-shaped corners protruding outward may be simply referred to as a substantially polygonal shape) from a thin flat plate material having conductivity (here, a copper plate), and is disposed such that the center of the chip spacer 122 and the center of the internal connecting terminal 134 coincide with each other. A diameter of the chip spacer 122 is set to be larger than a diameter of the internal connecting terminal 134. A depression 113 having a larger outer diameter than the outer diameter of the internal connecting terminal 134 is formed on an upper surface of the chip spacer 122, and the depression 113 is formed in a substantially polygonal shape when viewed in the up-down direction, more specifically a substantially quadrilateral shape, and further specifically a substantially quadrilateral shape with arc-shaped corners protruding outward (hereinafter, when the internal connecting terminal 154 is viewed in the up-down direction, a substantially polygonal shape, more specifically a substantially quadrilateral shape, and further specifically a substantially quadrilateral shape with arc-shaped corners protruding outward may be simply referred to as a substantially polygonal shape). The chip spacer 122 is bonded to a lower surface of the internal connecting terminal 134 in the depression 113 via a conductive bonding material (for example, solder BM 2). A lower surface of the chip spacer 122 is bonded to an upper surface (specifically, the electrodes (not shown)) of the electronic element 120 via a conductive bonding material (for example, solder BM 1).

In addition, protrusions 115 are formed on the lower surface of the chip spacer 122, and lower ends of the protrusions 115 come into contact with the electrodes of the electronic element 120, so that a distance between a bottom of the chip spacer 122 and the electronic element 120 can be maintained constant. Furthermore, a solder thickness of the solder BM 1 disposed between the chip spacer 122 and the electronic element 120 can be maintained constant. Recesses 117 corresponding to the protrusions 115 are formed on the upper surface of the chip spacer 122. Incidentally, the protrusions 115 are formed by applying a force in a vertically downward direction from above, for example, to four locations in the depression 113 of the chip spacer 122 using pins (not shown), but may be formed by other methods, for example, using a die. In addition, the recesses 117 are made when a force is applied in the vertically downward direction using pins to form the protrusions 115, the external shape of the recesses 117 is a shape corresponding to the shape of the protrusions 115, and the outer diameter or the depth of the recesses 117 changes according to the shape of the protrusions 115. In addition, it is preferable that the formation positions of the protrusions 115 and the recesses 117 are formed outside the position of an outer periphery of the internal connecting terminal 134 and inside the outer diameter of the chip spacer 122.

Further, it is preferable that at least one or more formation positions of the protrusions 115 and the recesses 117, each of which totals three or more, are formed on each side of a substantially polygonal shape, more specifically a substantially quadrilateral shape. The reason that the number of the protrusions 115 and the recesses 117 is set to at least three or more is to avoid affecting the upright standing of the chip spacer 122. In addition, when the cross-sectional shape of the internal connecting terminal 134 is a substantially polygonal shape when viewed in the up-down direction, more specifically a substantially quadrilateral shape, and further specifically a substantially quadrilateral shape with arc-shaped corners protruding outward (hereinafter, when the internal connecting terminal 154 is viewed in the up-down direction, a substantially polygonal shape, more specifically a substantially quadrilateral shape, and further specifically a substantially quadrilateral shape with arc-shaped corners protruding outward may be simply referred to as a substantially polygonal shape), it is desirable that similarly, the cross-sectional shape of the recesses 117 is a substantially polygonal shape when viewed in the up-down direction, more specifically a substantially quadrilateral shape, and further specifically a substantially quadrilateral shape with arc-shaped corners protruding outward (hereinafter, when the internal connecting terminal 154 is viewed in the up-down direction, a substantially polygonal shape, more specifically a substantially quadrilateral shape, and further specifically a substantially quadrilateral shape with arc-shaped corners protruding outward may be simply referred to as a substantially polygonal shape).

Incidentally, the chip spacer (not shown) is also disposed between a lower surface of the internal connecting terminal 154 and the electronic element 120 in the same manner as described above, but has the same structure and the like as described above, so that description thereof will be omitted.

The second connecting frame 142B is electrically connected to the second terminal 140. The second connecting frame 142B is embedded inside the sealing resin. In the electronic module 100, the second connecting frame 142B is formed integrally with the second terminal 140 from the same plate material 142. That is, a portion of the plate material 142, which is embedded in the sealing resin, corresponds to the second connecting frame 142B.

The second connecting frame 142B includes four through-holes (reference numeral is omitted) penetrating through the second connecting frame 142B in the up-down direction. The through-holes have a circular shape when viewed in the up-down direction. Upper end portions of internal connecting electrodes 144 are fitted into the four respective through-holes. The second connecting frame 142B and the electrodes (not shown) of the electronic element 120B are connected by the four internal connecting electrodes 144. The internal connecting electrodes 144 are fixed to the second connecting frame 142B, for example, by press-fitting. The number of the through-holes and the internal connecting electrodes 144 described above is not limited to four as long as necessary electric power can flow therethrough, and can be any number equal to or more than one.

The third connecting frame 152B is electrically connected to the third terminal 160. The third connecting frame 152B may be disposed on the same plane as the first connecting frame 132B and the second connecting frame 142B.

The third connecting frame 152B includes a through-hole (reference numeral is omitted) penetrating through the third connecting frame 152B in the up-down direction. The through-holes have a circular shape when viewed in the up-down direction. An upper end portion of the internal connecting terminal 154 serving as an internal connecting electrode is fitted into the through-hole. The third connecting frame 152B and the electrodes (not shown) of the electronic element 120 are connected by the internal connecting electrodes 144. The internal connecting terminal 154 is fixed to the third connecting frame 152B, for example, by press-fitting.

As shown in FIG. 1, the first terminal 130 is disposed at the front of the electronic module 100 in the front-rear direction. The first terminal 130 is configured from a plate material 132A formed in a plate shape from a flat plate material having conductivity, for example, a copper plate. The first terminal 130 includes a through-hole (reference numeral is omitted) penetrating through the first terminal 130 in the up-down direction. The through-hole has, for example, a circular shape when viewed in the up-down direction. Incidentally, the shape of the through-hole is not limited to a circular shape, and may be a polygonal shape such as a hexagonal shape.

An upper end of a first cap nut 230 is fitted into the through-hole. Here, it is preferable that a height of an upper surface of the first cap nut 230 is the same as a height of an upper surface of the first terminal 130 or lower than the height of the upper surface of the first terminal 130.

A lower surface of the first terminal 130 and the first cap nut 230 are embedded inside the sealing resin. On the other hand, the upper surface of the first terminal 130 is exposed to the outside of the sealing resin. Electrical connection between the first terminal 130 and an external connecting member (not shown) can be made by disposing the external connecting member on the upper surface of the first terminal 130 exposed from the sealing resin, and fixing the external connecting member to the first terminal 130 using a bolt (not shown).

As shown in FIGS. 1 to 3, the second terminal 140 is disposed at the rear of the electronic module 100 in the front-rear direction. The second terminal 140 is configured from a plate material 142A formed from a flat plate material having conductivity, for example, a copper plate. The second terminal 140 includes a through-hole (reference numeral is omitted) penetrating through the second terminal 140 in the up-down direction. The through-hole has, for example, a circular shape when viewed in the up-down direction.

An upper end of a second cap nut 240 is fitted into the through-hole. Here, it is preferable that a height of an upper surface of the second cap nut 240 is the same as a height of an upper surface of the second terminal 140 or lower than the height of the upper surface of the second terminal 140.

A lower surface of the second terminal 140 and the second cap nut 240 are embedded inside the sealing resin. On the other hand, the upper surface of the second terminal 140 is exposed to the outside of the sealing resin. Electrical connection between the second terminal 140 and an external connecting member (not shown) can be made by disposing the external connecting member on the upper surface of the second terminal 140 exposed from the sealing resin, and fixing the external connecting member to the second terminal 140 using a bolt (not shown).

The electronic module 100 may include the third terminal 160. The third terminal 160 is an optional component. As shown in FIG. 1, the third terminal 160 is formed from a flat plate material having conductivity, for example, a copper plate. The third terminal 160 is disposed such that the front-rear direction is a plate thickness direction, and has a long shape of which the longitudinal direction is the up-down direction. The third terminal 160 is disposed above the sealing resin, and includes a portion exposed from the sealing resin (hereinafter, referred to as an “upper portion”), and a portion covered by the sealing resin (hereinafter, referred to as a “lower portion”).

A through-hole (reference numeral is omitted) penetrating through the third terminal 160 in the front-rear direction is provided at the upper portion of the third terminal 160. Accordingly, an external connecting member (not shown) can be fixed to the third terminal 160 using a bolt (not shown) and a nut (not shown). Further, one end of a cap nut (not shown) may be fitted into the through-hole. Accordingly, when the external connecting member is fixed to the third terminal 160 using a bolt, electrical connection between the third terminal 160 and the external connecting member can be reliably made. The lower portion of the third terminal 160 is connected to the electrodes (not shown) of the electronic element 120.

According to the electronic module 100 of the first embodiment, since at least one depression having a larger diameter than the internal connecting terminal is formed on the upper surface of the chip spacer 122, it is possible to provide the electronic module 100 that suppresses misalignment between the internal connecting terminal 134 and the chip spacer 122, and that improves a desired self-alignment effect. In addition, it is possible to provide the electronic module that suppresses misalignment between the internal connecting terminal 134 and the chip spacer 122 and the rotation of the chip spacer 122 when the solder melts, and that improves a desired self-alignment effect, when the shape of the chip spacer 122 is increased according to the number of chip electrodes.

Further, according to the electronic module 100 according to the first embodiment, since the depression 113 having a larger outer diameter than the outer diameter of the internal connecting terminal 134 is formed in the chip spacer 122, the depression 113 can suppress the flow of the solder BM 2 outward in a radial direction from between the upper surface of the chip spacer 122 and the lower surface of the internal connecting terminal 134.

Furthermore, since the chip spacer 122 is disposed such that the center of the chip spacer 122 and the center of the internal connecting terminal 134 coincide with each other, rotational movement of the internal connecting terminal 134 when the solder solidifies can be suppressed.

Furthermore, even when the shape of the chip spacer 122 is increased according to the number of chip electrodes, the flow of the solder BM 2 outward in the radial direction from between the upper surface of the chip spacer 122 and the lower surface of the internal connecting terminal 134, and rotational movement of the internal connecting terminal 134 when the solder solidifies can be suppressed.

Further, since the cross section of the internal connecting terminal 134 is formed in a substantially polygonal shape, the rotation of the internal connecting terminal 134 can be suppressed.

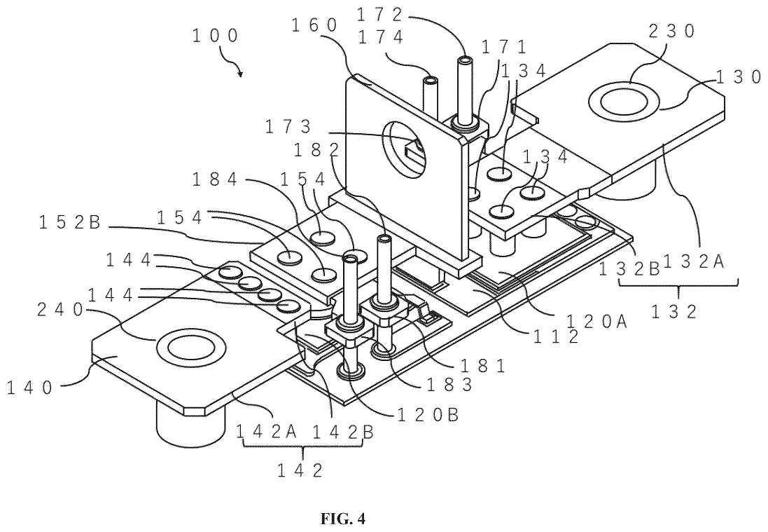

### (Referring to FIG. 4)

Incidentally, when the shape of the internal connecting terminal is a columnar shape, the rotational movement of the internal connecting terminal can be suppressed by using at least two or more internal connecting terminals. In the electronic module 100, at least one internal connecting terminal 134 is provided.

Further, since the cross section of the depression 113 is a substantially polygonal shape, the internal connecting terminal 134 is fitted into the depression 113, so that the flow of the solder BM 2 outward in the radial direction from between the upper surface of the chip spacer 122 and the lower surface of the internal connecting terminal 134, and rotational movement of the internal connecting terminal 134 when the solder solidifies can be suppressed.

Further, since the cross section of the chip spacer 122 is a substantially polygonal shape, the connection area with the chip spacer 122 and the electronic element 120 can be increased, and contact resistance can be reduced.

Further, since at least parts of the cross sections of the internal connecting terminal 134 and the depression 113 are formed in substantially the same polygonal shape, rotational movement of the internal connecting terminal 134 can be suppressed.

### Second Embodiment

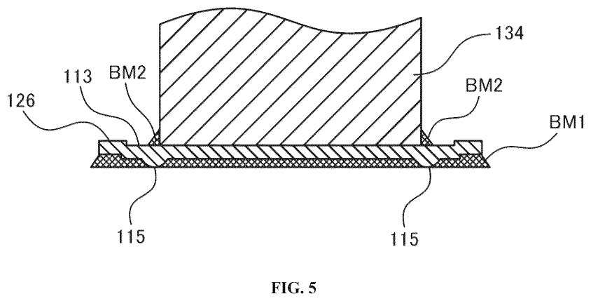

Hereinafter, an electronic module according to a second embodiment of the invention will be described with reference to FIG. 5. Incidentally, since the second embodiment is the same as the first embodiment described above except that the recesses 117 are not formed, only the different point will be described, and the description of the same portions will be omitted. As shown in FIG. 5, a chip spacer 126 is formed by shaping using a die such that only the protrusions 115 are formed without forming the recesses 117 shown in FIG. 2C. Even when only the protrusions 115 are formed without forming the recesses 117 in such a manner, the depression 113 having an annular shape and having a larger outer diameter than the diameter of the internal connecting terminal 134 is formed in the chip spacer 126.

Therefore, by forming the depression 113 having a larger outer diameter than the diameter of the internal connecting terminal 134 in the chip spacer 126, the flow of the solder BM 2 outward in the radial direction from between an upper surface of the chip spacer 122 and the lower surface of the internal connecting terminal 134 can be suppressed. Further, since the protrusions 115 are formed on a lower surface of the chip spacer 126, the protrusions 115 can cause self-alignment when the solder BM 1 solidifies to act toward an axis of the internal connecting terminal 134.

Incidentally, the invention is not limited to the embodiments described above, and it goes without saying that the invention can be modified and applied in various modes within the scope of the invention described in the claims.

That is, in the embodiments described above, the depression 113 having a larger diameter than the internal connecting terminal 134 is formed on the upper surface of the chip spacer 122; however, a plurality of the depressions 113 having a large diameter may be formed according to the number of the internal connecting terminals 134. Namely, the technical effects of the invention can be achieved as long as at least one depression 113 having a larger diameter than the internal connecting terminal 134 is formed on the upper surface of the chip spacer 122.

In addition, in the embodiments described above, the cross section of the internal connecting terminal 134 is formed in a substantially polygonal shape; however, a part thereof may be formed in a substantially polygonal shape. That is, the technical effects of the invention can be achieved as long as at least a part of the cross section of the internal connecting terminal 134 is formed in a substantially polygonal shape.

In addition, in the embodiments described above, the cross section of the depression 113 is formed in a substantially polygonal shape; however, a part thereof may be formed in a substantially polygonal shape. That is, the technical effects of the invention can be achieved as long as at least a part of the cross section of the depression 113 is formed in a substantially polygonal shape.

Furthermore, in the embodiments described above, the chip spacer 122 is formed in a substantially polygonal shape; however, a part thereof may be formed in a substantially polygonal shape. That is, the technical effects of the invention can be achieved as long as at least a part of the chip spacer 122 is formed in a substantially polygonal shape.

### EXPLANATIONS OF LETTERS OR NUMERALS

100 ELECTRONIC MODULE
112 INSULATING SUBSTRATE
113 DEPRESSION
115 PROTRUSION
117 RECESS
120 SEMICONDUCTOR ELEMENT (ELECTRONIC ELEMENT)
122 CHIP SPACER
130 FIRST TERMINAL
132A, 142A, 160A FLAT PLATE MATERIAL
134, 154 INTERNAL CONNECTING TERMINAL
140 SECOND TERMINAL
132B, 142B, 152B CONNECTING FRAME
160 THIRD TERMINAL
170 SEALING RESIN

What is claimed is:

1. An electronic module comprising:
an electronic element;
at least one internal connecting terminal electrically connected to the electronic element, and having conductivity; and
a chip spacer formed between a lower end surface of the internal connecting terminal and the electronic element,
wherein the chip spacer is bonded to the electronic element via a conductive bonding material, and at least one depression having a larger diameter than the internal connecting terminal is formed on an upper surface of the chip spacer.

2. The electronic module according to claim 1,
wherein at least a part of the internal connecting terminal is formed in a substantially polygonal shape.

3. The electronic module according to claim 1,
wherein at least a part of the depression has a substantially polygonal shape.

4. The electronic module according to claim 3,
wherein at least the parts of the internal connecting terminal and the depression are formed in substantially the same polygonal shape.

5. The electronic module according to claim 1,
wherein at least a part of the chip spacer has a substantially polygonal shape.

6. The electronic module according to claim 2,
wherein at least a part of the depression has a substantially polygonal shape.

7. The electronic module according to claim 6,
wherein at least the parts of the internal connecting terminal and the depression are formed in substantially the same polygonal shape.
